(19) United States
(12) Patent Application Publication
(10) Pub. No.: US 2010/0051925 A1
(43) Pub. Date: Mar. 4, 2010

(54) ORGANIC LIGHT EMITTING DIODE DISPLAY DEVICE AND METHOD OF FABRICATING THE SAME

(76) Inventors: Sam-Il Kho, Yongin-city (KR); Hee-Seong Jeong, Yongin-city (KR); Byeong-Wook Yoo, Yongin-city (KR); Gun-Shik Kim, Yongin-city (KR); Seong-Taek Lee, Yongin-city (KR); Jun-Sik Oh, Yongin-city (KR)

Correspondence Address: CHRISTIE, PARKER & HALE, LLP, PO BOX 7068, PASADENA, CA, 91109-7068, US

(21) Appl. No.: 12/550,255

(22) Filed: Aug. 28, 2009

(30) Foreign Application Priority Data
Aug. 29, 2008 (KR) 10-2008-0085177

(51) Int. Cl. H01L 51/52

(52) U.S. Cl. 257/40; 438/29; 257/98; 438/99; 257/E51.022

(57) ABSTRACT

An organic light emitting diode (OLED) display device which can improve emission efficiency and reduce (or minimize) resonance effect, and a method of fabricating the same. The OLED display device includes a substrate; a first electrode disposed on the substrate and including a reflective layer; an organic layer disposed on the first electrode and including a white emission layer and a hole injection layer having a thickness between 200 and 300 Å; and a second electrode disposed on the organic layer.

### CROSS-REFERENCE TO RELATED APPLICATION

This application claims priority to and the benefit of Korean Patent Application No. 10-2008-0085177, filed Aug. 29, 2008, the entire content of which is incorporated herein by reference.

### BACKGROUND OF THE INVENTION

1. Field of the Invention

The present invention relates to an organic light emitting diode (OLED) display device and a method of fabricating the same to improve emission efficiency and/or reduce resonance effect.

2. Description of the Related Art

An OLED display device includes a substrate, an anode disposed on the substrate, an emission layer disposed on the anode, and a cathode disposed on the emission layer. In the OLED display device, when a voltage is applied between the anode and the cathode, holes and electrons are injected into the emission layer and recombined to produce excitons, which transition from an excited state to a ground state and emit light.

To implement a full-color OLED display device, an emission layer for each of red (R), green (G) and blue (B) light is needed. However, the respective R, G and B emission layers of an OLED display device exhibit different emission efficiencies (Cd/A). Accordingly, each emission layer exhibits different brightness, when the same current level is applied. That is, when an equal amount of current is applied, one color exhibits low brightness, and another color exhibits high brightness, so that it is difficult to obtain appropriate color balance or white balance in the OLED display device. For example, since the emission efficiency of the green emission layer is 3 to 6 times higher than those of the red and blue emission layers, more current has to be applied to the red and blue emission layers in order to adjust the white balance.

To help solve this problem, a method has been provided to include the step of forming an emission layer, which emits light of single color (i.e., white light), and the step of forming a color filter layer for extracting light corresponding to a preset color from the emission layer or forming a color conversion layer for converting the light generated from the emission layer into the light of the preset color.

FIG. 1 is a schematic cross-sectional view of a conventional top-emission OLED display device.

Referring to FIG. 1, a substrate 100 is provided, and a first electrode 110 having a reflective layer is formed on the substrate 100. A thin film transistor and a capacitor may be further included between the first electrode 110 and the substrate 100.

An organic layer 120 having an emission layer is formed on the first electrode 110. The emission layer may be a single layer or a multilayer. A second electrode 130 that is a semitransparent electrode is formed on the organic layer 120, and thus the OLED display device is completed.

However, the conventional top-emission OLED display device exhibits resonance effect due to the second electrode that is a semitransparent electrode. In addition, when a white emission layer and a color filter are used to implement full color, the white emission layer is formed by sequentially stacking blue, green and red emission layers. However, white light may not be properly maintained because the color peaks may not be properly implemented due to the resonance effect caused by the semitransparent electrode. Also, the resonance effect may not be prevented even when a transparent second electrode is used because of wide angle interference.

### SUMMARY OF THE INVENTION

Aspects of embodiments of the present invention are directed toward an organic light emitting diode (OLED) display device in which the thickness of a hole injection layer is controlled in order to reduce or minimize resonance effect, and a method of fabricating the same.

According to an embodiment of the present invention, an OLED display device includes: a substrate; a first electrode disposed on the substrate and including a reflective layer; an organic layer disposed on the first electrode and including a white emission layer and a hole injection layer having a thickness between about 200 to about 300 Å; and a second electrode disposed on the organic layer.

According to another embodiment of the present invention, a method of fabricating an OLED display device includes: preparing a substrate; forming a first electrode including a reflective layer on the substrate; forming an organic layer, including an organic white emission layer and a hole injection layer having a thickness between about 200 and about 300 Å, on the first electrode; and forming a second electrode on the organic layer.

A more complete understanding of the organic light emitting diode display device and method of fabricating the same will be afforded to those skilled in the art, by a consideration of the following detailed description. Reference will be made to the appended sheets of drawings, which will first be described briefly.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a schematic cross-sectional view of a conventional organic light emitting diode (OLED) display device;

FIG. 2 is a schematic cross-sectional view of an OLED display device according to an exemplary embodiment of the present invention;

FIG. 3 is a graph showing an EL spectrum of Example 1;

FIG. 4 is a graph showing an EL spectrum of Example 2;

FIG. 5 is a graph showing an EL spectrum of Comparative Example 1; and

FIG. 6 is a graph showing an EL spectrum of Comparative Example 2.

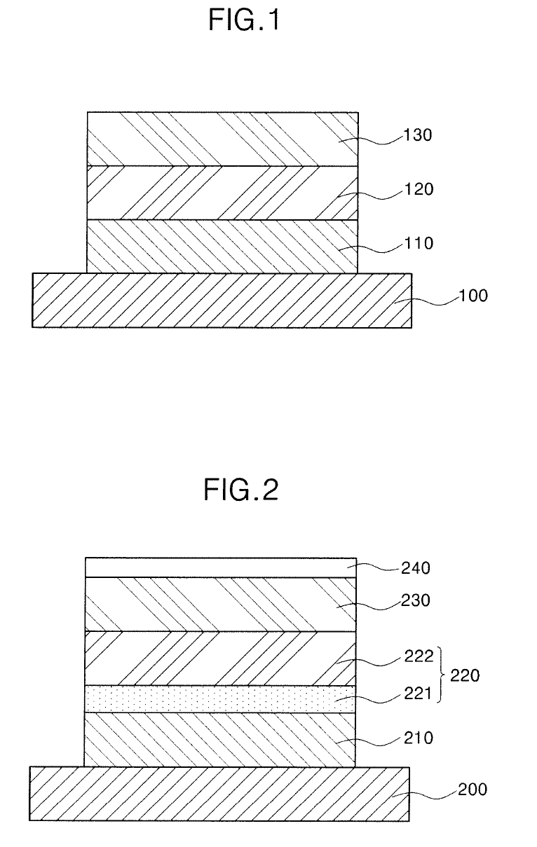

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when an element is referred to as being “on” another element, it can be directly on the another element or be indirectly on the another element with one or more intervening elements interposed therebetween. Like reference numerals designate like elements throughout the specification.

FIG. 2 is a schematic cross-sectional view of an organic light emitting diode (OLED) display device according to an exemplary embodiment of the present invention.

Referring to FIG. 2, a substrate 200 is provided, and a first electrode 210 having a reflective layer is formed on the substrate 200. The first electrode 210 may have a double- or triple-layer structure. When the first electrode 210 has a double-layer structure, it may have a reflective layer formed of aluminum, silver or an alloy thereof and a transparent conductive layer formed of indium tin oxide (ITO), indium zinc oxide (IZO) or indium tin-zinc oxide (ITZO), which are sequentially stacked. Alternatively, when the first electrode 21 has a triple-layer structure, it may have a first metal layer formed of titanium, molybdenum, ITO or an alloy thereof, a second metal layer formed of aluminum, silver or an alloy thereof and a third metal layer formed of ITO, IZO or ITZO, which are sequentially stacked.

A thin film transistor and a capacitor may be further included between the substrate 200 and the first electrode 210.

An organic layer 220 including a white emission layer 222 and a hole injection layer 221 having a thickness between 200 and 300 Å is formed on the first electrode 210.

In addition, in a top-emission structure, light generated from the white emission layer 222 is directly emitted through a second electrode, or is reflected by the first electrode 210 and then emitted through the second electrode. In the latter case, while resonance effect due to wide angle interference and multiple beam interference may be exhibited, it may be reduced (or minimized) by limiting the hole injection layer 221 to the above-mentioned thickness. If the hole injection layer 221 is thick, a transmission spectrum moves to a long wavelength, and thus transmittance is reduced and emission efficiency is reduced particularly in a blue region. However, in one embodiment, when the hole injection layer 221 is limited to the above-mentioned thickness (i.e., between 200 and 300 Å), the transmission spectrum is disposed in a visible ray region, and thus transmittance is increased, a driving voltage is reduced and emission efficiency is increased.

The hole injection layer 221 may be formed of an aryl amine-based compound and/or one or more starburst-type amines. More particularly, the hole injection layer 221 may be formed of 4,4,4-tris(3-methylphenyl(phenyl)amino)triphenylamine (m-MTDATA), 1,3,5-tris[4-(3-methylphenyl(phenyl)amino)phenyl]benzene (m-MTDATB) and/or copper phthalocyanine (CuPc).

The white emission layer 222 may be a single layer or a multilayer. When the white emission layer is a single layer, white light may be obtained by adding emitting materials exhibiting respective colors and dopants, or mixing PBD, TPB, Coumarin6, DCM1 and Nile red with a carbazole-based molecule, i.e., PVK, at an appropriate ratio. In addition, a white emitting material may be obtained by mixing two different color emitting materials together and adding another emitting material thereto. For example, the white emitting material may be obtained by mixing a red emitting material and a green emitting material and then adding a blue emitting material thereto. The red emitting material includes a material selected from the group consisting of a polymer (such as polythiophene (PT)) and its derivatives. Also, the green emitting material includes a material selected from the group consisting of small molecular materials, such as an aluminum-quinoline complex (Alq3), BeBq2 and Almq, a polymer (such as poly(p-phenylenevinylene) (PPV)) and its derivatives. In addition, the blue emitting material includes a material selected from the group consisting of small molecular materials, such as ZnPBO, Balq, DPVBi and OXA-D, a polymer (such as polyphenylene (PPP)) and its derivatives.

When the white emission layer 222 is a multilayer structure, it may be a double-layer structure for emitting light having different wavelengths, which includes an emission layer for emitting light in an orange-red region and an emission layer for emitting light in a blue region. Also, the emission layer for emitting light in an orange-red region may be a phosphorescent emission layer, and the emission layer for emitting light in a blue region may be a fluorescent emission layer. The phosphorescent emission layer has a better emission characteristic than the fluorescent emission layer for emitting light in the same wavelength. But, the fluorescent emission layer has a longer lifespan than the phosphorescent emission layer. As such, in one embodiment, the white emission layer is formed by stacking both the phosphorescent emission layer for emitting light in an orange-red region and the fluorescent emission layer for emitting light in a blue region together so that the white emission can have both higher emission efficiency and longer lifespan. Also, the double white emission layer may be formed of a polymer, a small molecule material or a combination thereof.

When the white emission layer 222 is a triple-layer structure, it may have a stacked structure of red, green and blue emission layers, but a stacking order thereof is not specifically limited thereto.

The red emission layer may include a small molecular material such as Alq3, Alq3(host)/DCJTB(fluorescent dopant), Alq3(host)/DCM(fluorescent dopant), or CBP(host)/PtOEP(phosphorescent organic metal complex); and/or a polymer such as a PFO-based polymer or a PPV-based polymer.

The green emission layer may include a small molecular material such as Alq3, Alq3(host)/C545t(dopant) or CBP(host)/IrPPY(phosphorescent organic complex); and/or a polymer such as a PFO-based polymer or a PPV-based polymer.

The blue emission layer may include a small molecular material such as DPVBi, spiro-DPVBi, spiro-6P, distyrylbenzene (DSB) or distyrylarylene (DSA); and/or a polymer such as a PFO-based polymer or a PPV-based polymer.

The organic layer 220 may be a single layer or multilayer structure that includes a hole transport layer, an electron injection layer, an electron transport layer and/or a hole blocking layer.

The hole transport layer may be disposed between the hole injection layer 221 and the white emission layer 220, and formed of an arylene diamine derivative, a starburst compound, a biphenyl diamine derivative having a spiro group and a ladder-type compound. To be specific, the hole transport layer may be formed of N,N-diphenyl-N,N-bis(4-methylphenyl)-1,1 -biphenyl-4,4-diamine (TPD) and/or 4,4-bis[N-(1-naphthyl)-N-phenylamino]biphenyl (NPB).

The hole blocking layer serves to reduce (or prevent) the movement of holes to the electron injection layer when electron mobility is larger than hole mobility in the organic emission layer. Here, the hole blocking layer may be formed of 2-biphenyl-4-yl-5-(4-t-butylphenyl)-1,3,4-oxydiazole (PBD) and/or spiro-PBD or 3-(4-t-butylphenyl)-4-phenyl-5-(4-biphenyl)-1,2,4-triazole (TAZ).

The electron transport layer may be formed of a metal compound that is capable of accepting an electron, and particularly, aluminum tris(8-hydroxyquinoline) (Alq3) capable of stably transporting electrons provided from a cathode electrode.

The electron injection layer may be formed of 1,3,4-oxydiazol derivatives, 1,2,4-triazole derivatives and/or LiF.

Also, the organic layer 220 may be formed by vacuum deposition, inkjet printing and/or laser induced thermal imaging.

A second electrode 230, which is a semitransparent electrode, is formed on the organic layer 220. The second electrode 230 may be formed of magnesium-silver (MgAg) and/or aluminum-silver (AlAg). Here, the magnesium-silver alloy may be formed by co-deposition of magnesium and silver, and the aluminum-silver alloy may be formed by sequential deposition of aluminum and silver. Also, a transparent conductive layer such as ITO or IZO may be further formed on the second electrode 230.

In another embodiment, a transmittance controlled layer 240 is formed on the second electrode 230 as also shown in FIG. 2. The transmittance controlled layer 240 controls transmittance and reflectance of the second electrode 230 using an interference effect, thereby controlling intensity per wavelength band of a transmission spectrum. To be specific, the OLED display device for emitting white light has to exhibit almost similar transmittance in a visible ray wavelength band (particularly between 450 and 650nm). However, since the red (R), green (G) and blue (B) intensities of a light source spectrum are different from one another, the transmittance controlled layer is provided to control this difference. Accordingly, the OLED display device for emitting white light with the transmittance controlled layer may now uniformly implement the red (R), green (G) and blue (B) peaks.

Here, materials having excessive absorption and reflection characteristics are not suitable for use as the transmittance controlled layer. As such, pure metals or materials having low transmittance will be excluded. Here, the transmittance controlled layer is formed of a material selected from the group consisting of SiNx, SiO₂, SiON, MgF₂, ZnS, ZnSe, TeO₂, ZrO₂, arylenediamine derivatives, triamine derivatives, CBP, an aluminum-quinoline (Alq3) complex, and combinations thereof. Also, the transmittance controlled layer may be formed by vacuum deposition or lithography.

As a result, the OLED display device according to the exemplary embodiment of the present invention is completed.

The present invention will be described in more detail with reference to the following examples. However, these examples are for illustrative purposes only and are not intended to limit the scope of the present invention.

### EXAMPLE 1

Silver was formed to a thickness of 1000 Å on a substrate, and ITO was formed to a thickness of 70 Å on the silver. A hole injection layer was formed to a thickness of 200 Å on the ITO using IDE406 (Idemitsu), and a hole transport layer was formed to a thickness of 150 Å on the hole injection layer using IDE320 (Idemitsu). A blue emission layer containing BH215 (Idemitsu) as a host material and 1 wt % BD052 (Idemitsu) as a dopant material was formed to a thickness of 80 Å on the hole transport layer, and a green emission layer containing CBP (UDC) as a host material and 7 wt % GD33 (UDC) as a dopant material was formed to a thickness of 120 Å on the blue emission layer. Also, a red emission layer containing CBP (UDC) as a host material and 12 wt % TER004 (COVION) as a dopant material was formed to a thickness of 100 Å on the green emission layer. A hole blocking layer was formed to a thickness of 50 Å on the red emission layer using Balq (UDC), and an electron transport layer was formed to a thickness of 100 Å on the hole blocking layer using Alq3. An electron injection layer was formed to a thickness of 5 Å on the electron transport layer using LiF. A second electrode was formed by stacking Al to a thickness of 20 Å and Ag to a thickness of 70 Å on the electron injection layer.

### EXAMPLE 2

Silver was formed to a thickness of 1000 Å on a substrate, and ITO was formed to a thickness of 70 Å on the silver. A hole injection layer was formed to a thickness of 300 Å on the ITO using IDE406 (Idemitsu), and a hole transport layer was formed to a thickness of 150 Å on the hole injection layer using IDE320 (Idemitsu). A blue emission layer containing BH215 (Idemitsu) as a host material and 1 wt % BD052 (Idemitsu) as a dopant material was formed to a thickness of 80 Å on the hole transport layer, and a green emission layer containing CBP (UDC) as a host material and 7 wt % GD33 (UDC) as a dopant material was formed to a thickness of 120 Å on the blue emission layer. Also, a red emission layer containing CBP (UDC) as a host material and 12 wt % TER004 (COVION) as a dopant material was formed to a thickness of 100 Å on the green emission layer. A hole blocking layer was formed to a thickness of 50 Å on the red emission layer using Balq (UDC), and an electron transport layer was formed to a thickness of 100 Å on the hole blocking layer using Alq3. An electron injection layer was formed to a thickness of 5 Å on the electron transport layer using LiF. A second electrode was formed by stacking Al to a thickness of 20 Å and Ag to a thickness of 70 Å on the electron injection layer.

### COMPARATIVE EXAMPLE 1

Silver was formed to a thickness of 1000 Å on a substrate, and ITO was formed to a thickness of 70 Å on the silver. A hole injection layer was formed to a thickness of 100 Å on the ITO using IDE406 (Idemitsu), and a hole transport layer was formed to a thickness of 150 Å on the hole injection layer using IDE320 (Idemitsu). A blue emission layer containing BH215 (Idemitsu) as a host material and 1 wt % BD052 (Idemitsu) as a dopant material was formed to a thickness of 80 Å on the hole transport layer, and a green emission layer containing CBP (UDC) as a host material and 7 wt % GD33 (UDC) as a dopant material was formed to a thickness of 120 Å on the blue emission layer. Also, a red emission layer containing CBP (UDC) as a host material and 12 wt % TER004 (COVION) as a dopant material was formed to a thickness of 100 Å on the green emission layer. A hole blocking layer was formed to a thickness of 50 Å on the red emission layer using Balq (UDC), and an electron transport layer was formed to a thickness of 100 Å on the hole blocking layer using Alq3. An electron injection layer was formed to a thickness of 5 Å on the electron transport layer using LiF. A second electrode was formed by stacking Al to a thickness of 20 Å and Ag to a thickness of 70 Å on the electron injection layer.

### COMPARATIVE EXAMPLE 2

Silver was formed to a thickness of 1000 Å on a substrate, and ITO was formed to a thickness of 70 Å on the silver. A hole injection layer was formed to a thickness of 400 Å on the ITO using IDE406 (Idemitsu), and a hole transport layer was formed to a thickness of 150 Å on the hole injection layer using IDE320 (Idemitsu). A blue emission layer containing BH215 (Idemitsu) as a host material and 1 wt % BD052 (Idemitsu) as a dopant material was formed to a thickness of 80 Å on the hole transport layer, and a green emission layer containing CBP (UDC) as a host material and 7 wt % GD33 (UDC) as a dopant material was formed to a thickness of 120 Å on the blue emission layer. Also, a red emission layer containing CBP (UDC) as a host material and 12 wt % TER004 (COVION) as a dopant material was formed to a thickness of 100 Å on the green emission layer. A hole blocking layer was formed to a thickness of 50 Å on the red emission layer using Balq (UDC), and an electron transport layer was formed to a thickness of 100 Å on the hole blocking layer using Alq3. An electron injection layer was formed to a thickness of 5 Å on the electron transport layer using LiF. A second electrode was formed by stacking Al to a thickness of 20 Å and Ag to a thickness of 70 Å on the electron injection layer.

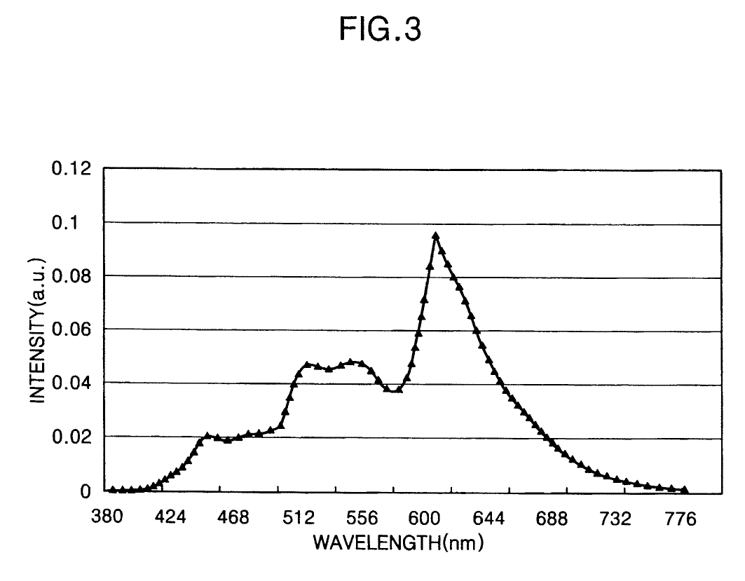

FIGS. 3 to 6 are graphs showing EL spectrums of Examples 1 and 2 and Comparative Examples 1 and 2. In each of FIGS. 3 to 6, an x axis represents wavelength (nm), and a y axis represents intensity (arbitrary unit (a.u.)).

Referring to FIG. 3, the EL spectrum of Example 1 shows a blue peak having an intensity of 0.02 (a.u.) in a wavelength band between 424 and 468 nm, and a green peak having an intensity of 0.048 (a.u.) in a wavelength band between 512 and 556 nm. In addition, a red peak having an intensity of 0.095 (a.u.) is shown in a wavelength band between 600 and 644 nm.

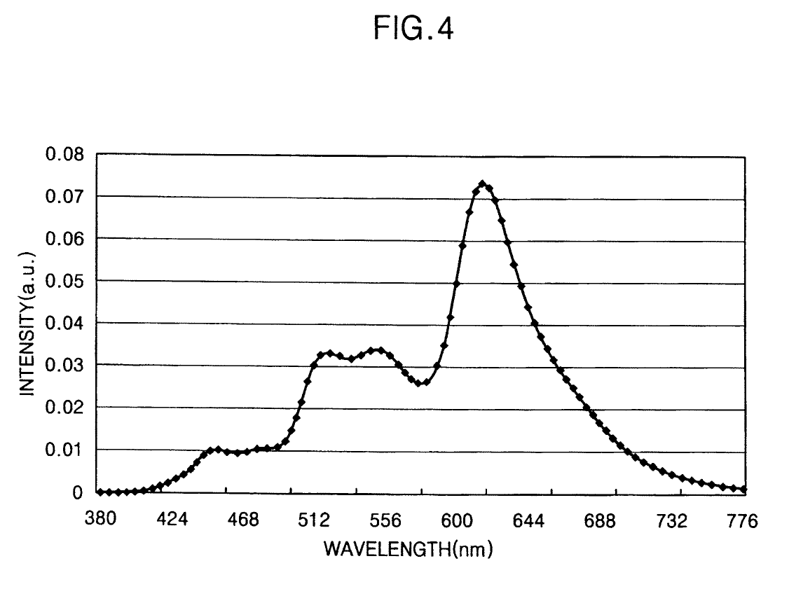

Referring to FIG. 4, the EL spectrum of Example 2 shows a blue peak having an intensity of 0.01 in a wavelength band between 424 and 468 nm, and a green peak having an intensity of 0.034 in a wavelength band between 512 and 556 nm. In addition, a red peak having an intensity of 0.074 is shown in a wavelength band between 600 and 644 nm.

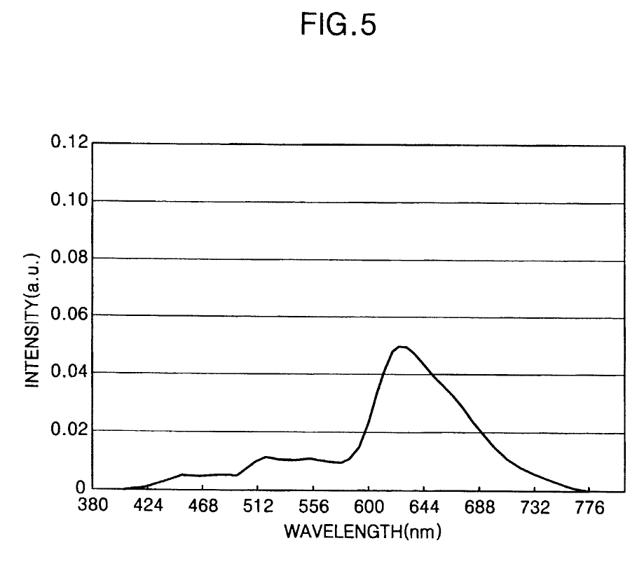

Referring to FIG. 5, the EL spectrum of Comparative Example 1 shows a blue peak having an intensity of 0.34 in a wavelength band between 424 and 468 nm, and a green peak having an intensity of 0.11 in a wavelength band between 512 and 556 nm. In addition, a red peak having an intensity of 0.048 is shown in a wavelength band between 600 and 644 nm.

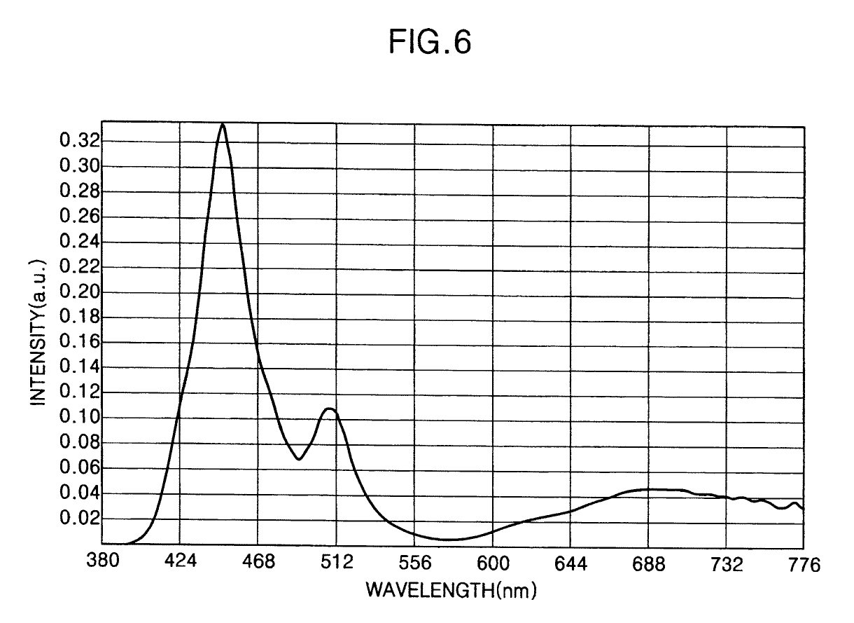

Referring to FIG. 6, the EL spectrum of Comparative Example 2 shows a blue peak having an intensity of 0.005 in a wavelength band between 424 and 468 nm, and a green peak having an intensity of 0.01 in a wavelength band between 512 and 556 nm. In addition, a red peak having an intensity of 0.05 is shown in a wavelength band between 600 and 644 nm.

Compared with the EL spectrums of Examples 1 and 2 and Comparative Examples 1 and 2, the three peaks of R, G and B are strongly shown in Examples 1 and 2. However, in Comparative Example 1, the blue peak is very strong but the green and red peaks are very weak. On the other hand, in Comparative Example 2, the red peak is very strong, but the green and blue peaks are very weak.

It can be derived from the above graphical results that in Examples 1 and 2, all R, G and B peaks are strongly shown, but in Comparative Examples 1 and 2, R, G and B peaks are not uniformly shown.

Therefore, in order to strongly implement white emission, the hole injection layer has to be formed to the above-mentioned thickness in Example 1 or 2.

TABLE 1

| | Brightness | Driving | Emission efficiency |
|---|---|---|---|
| | (nit) | voltage (V) | (Cd/A) |
| Example 1 | 1000 | 7.64 | 7.45 |
| Example 2 | 1000 | 7.64 | 7.45 |

Table 1 shows the comparison of driving voltage and emission efficiency at the same brightness in Examples 1 and 2.

Referring to Table 1, in Examples 1 and 2, the driving voltage is 7.64V, and the emission efficiency is 7.45Cd/A, which are the same as each other.

It can be noted from the results that Examples 1 and 2 show a bit difference in intensities between the three peaks of R, G and B (see FIGS. 4 and 5) but the same driving voltage and emission efficiency.

In an embodiment of the present invention, the thickness of a hole injection layer is controlled and thus resonance effect can be reduced (or minimized), thereby providing an OLED display device having decreased driving voltage and increased emission efficiency (or allowing the OLED display device to be driven with lower voltage and with increased emission efficiency).

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An organic light emitting diode (OLED) display device, comprising:
a substrate;
a first electrode on the substrate and comprising a reflective layer;
an organic layer on the first electrode and comprising a white emission layer and a hole injection layer having a thickness between about 200 and about 300 Å; and
a second electrode on the organic layer.

2. The OLED display device according to claim 1, wherein the reflective layer comprises a material selected from the group consisting of silver, aluminum and alloys thereof.

3. The OLED display device according to claim 1, wherein the white emission layer is a single layer.

4. The OLED display device according to claim 1, wherein the white emission layer is a multilayer.

5. The OLED display device according to claim 4, wherein the multilayer comprises an orange-red emission layer and a blue emission layer.

6. The OLED display device according to claim 4, wherein the multilayer comprises a blue emission layer, a green emission layer and a red emission layer.

7. The OLED display device according to claim 1, wherein the second electrode comprises a material selected from the group consisting of a magnesium-silver (MgAg) alloy, an aluminum-silver (AlAg) alloy, and combinations thereof.

8. The OLED display device according to claim 1, further comprising:
a transmittance controlled layer on the second electrode.

9. The OLED display device according to claim 8, wherein the transmittance controlled layer comprises a material selected from the group consisting of SiNx, SiO₂, SiON, MgF₂, ZnS, ZnSe, TeO₂, ZrO₂, arylenediamine derivatives, triamine derivatives, CBP, an aluminum-quinoline (Alq3) complex, and combinations thereof.

10. A method of fabricating an organic light emitting diode (OLED) display device, the method comprising:
preparing a substrate;
forming a first electrode comprising a reflective layer on the substrate;
forming an organic layer, comprising an organic white emission layer and a hole injection layer having a thickness between about 200 and about 300 Å, on the first electrode; and
forming a second electrode on the organic layer.

11. The method according to claim 10, wherein the organic layer is formed by a process selected from the group consisting of vacuum deposition, laser induced thermal imaging, inkjet printing, and combinations thereof.

12. An organic light emitting diode (OLED) display device, comprising:
a substrate;
an organic hole injection layer having a thickness between about 200 and about 300 Å;
a first electrode comprising a reflective layer and between the organic hole injection layer and the substrate;
a second electrode; and
an organic white emission layer between the organic hole injection layer and the second electrode.

13. The OLED display device according to claim 12, wherein the reflective layer comprises a material selected from the group consisting of silver, aluminum and alloys thereof.

14. The OLED display device according to claim 12, wherein the organic white emission layer is a single layer.

15. The OLED display device according to claim 12, wherein the organic white emission layer is a multilayer.

16. The OLED display device according to claim 15, wherein the multilayer comprises an orange-red emission layer and a blue emission layer.

17. The OLED display device according to claim 15, wherein the multilayer comprises a blue emission layer, a green emission layer and a red emission layer.

18. The OLED display device according to claim 12, wherein the second electrode comprises a material selected from the group consisting of a magnesium-silver (MgAg) alloy, an aluminum-silver (AlAg) alloy, and combinations thereof.

19. The OLED display device according to claim 12, further comprising:
a transmittance controlled layer on the second electrode and comprising a material selected from the group consisting of SiNx, SiO₂, SiON, MgF₂, ZnS, ZnSe, TeO₂, ZrO₂, arylenediamine derivatives, triamine derivatives, CBP, an aluminum-quinoline (Alq3) complex, and combinations thereof.
